(19) United States
(12) Patent Application Publication
(10) Pub. No.: US 2013/0146333 A1
(43) Pub. Date: Jun. 13, 2013

(54) TOUCH PANEL, METHOD FOR FORMING THE SAME, AND DISPLAY SYSTEM

(71) Applicants: Innocom Technology (Shenzhen) CO., LTD, Shenzhen City (TW); Chimei Innolux Corporation, Chu-Nan (TW)

(72) Inventor: Ya-Yin CHENG, Chu-Nan (TW)

(73) Assignees: CHIMEI INNOLUX CORPORATION, Chu-Nan (TW); INNOCOM TECHNOLOGY (SHENZHEN) CO., LTD., Shenzhen City (TW)

(21) Appl. No.: 13/706,912

(22) Filed: Dec. 6, 2012

(30) Foreign Application Priority Data
Dec. 8, 2011 (TW) 100145290

(51) Int. Cl. H05K 3/06; H05K 1/02

(52) U.S. Cl. CPC H05K 3/064; H05K 1/0213
USPC 174/250; 216/13

(57) ABSTRACT

A method for forming a touch panel includes: providing a substrate; forming a transparent conducting layer on the substrate; forming a conducting layer on the transparent conducting layer; forming a photoresist layer on the conducting layer, wherein the photoresist layer has a first portion, a second portion, and an opening partially exposing the conducting layer, and the first portion is thicker than the second portion; using the photoresist layer as a mask to etch and remove the exposed conducting layer and the transparent conducting layer thereunder such that the transparent conducting layer is formed to be a transparent conducting pattern layer; removing the second portion to expose a portion of the conducting layer thereunder; using the photoresist layer as a mask to etch and remove the exposed conducting layer such that the conducting layer is formed to be a wire layer; and removing the photoresist layer.

### CROSS REFERENCE TO RELATED APPLICATIONS

This application claims priority of Taiwan Patent Application No. 100145290, filed on Dec. 8, 2011, the entirety of which is incorporated by reference herein.

### BACKGROUND OF THE INVENTION

1. Field of the Invention

The invention relates to a touch panel and method for forming the same, and in particular relates to a formation method for a touch panel which needs less photolithography processes.

2. Description of the Related Art

Typically, an indium tin oxide (ITO) layer is used as a touch-control electrode in a touch-control sensing region of a touch panel. A metal layer is used as a wire layer electrically connected to the touch-control electrode. Thus, the formation of a touch panel needs photolithography processes requiring at least two photomasks, which are photolithography processes of the indium tin oxide layer and the metal layer, respectively. In this case, fabrication time and cost of the touch panel is high. In addition, alignment mismatch between the two photolithography processes may negatively affect the quality of the touch panel.

Therefore, a novel fabrication process of a touch panel is desired in hope of reducing and/or preventing the problems mentioned above.

### BRIEF SUMMARY OF THE INVENTION

According to an embodiment of the invention, a method for forming a touch panel is provided. The method includes: providing a substrate; forming a transparent conducting layer on the substrate; forming a conducting layer on the transparent conducting layer; forming a photoresist layer on the conducting layer, wherein the photoresist layer has a first portion, a second portion, and at least one opening, and the first portion has a thickness larger than that of the second portion, and the opening exposes a portion of the conducting layer; using the photoresist layer as a mask to etch and remove the exposed conducting layer and the transparent conducting layer thereunder such that the transparent conducting layer is formed to be a transparent conducting pattern layer; removing the second portion of the photoresist layer to expose a portion of the conducting layer thereunder; using the photoresist layer as a mask to etch and remove the exposed conducting layer such that the conducting layer is formed to be a wire layer; and removing the photoresist layer.

According to an embodiment of the invention, a touch panel is provided. The touch panel includes: a substrate; a transparent conducting pattern layer disposed on the substrate; and a wire layer formed on the transparent conducting pattern layer, wherein a lower surface of the wire layer is separated from the substrate by a portion of the transparent conducting pattern layer.

According to an embodiment of the invention, a display system is provided. The display system includes: a display panel; and a touch panel disposed on the display panel, wherein the touch panel includes: a substrate; a transparent conducting pattern layer disposed on the substrate; and a wire layer formed on the transparent conducting pattern layer, wherein a lower surface of the wire layer is separated from the substrate by a portion of the transparent conducting pattern layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A is a top view showing a touch panel according to an embodiment of the present invention;

FIG. 1B is a top view partially showing a touch panel according to an embodiment of the present invention;

FIGS. 2A-2F are cross-sectional views showing the steps of forming a touch panel according to an embodiment of the present invention;

FIG. 3A is a top view showing a touch panel according to an embodiment of the present invention;

FIG. 3B is a top view partially showing a touch panel according to an embodiment of the present invention;

FIGS. 4A-4G are cross-sectional views showing the steps of forming a touch panel according to an embodiment of the present invention; and

FIGS. 5A-5B are cross-sectional views showing display systems according to embodiments of the present invention, respectively.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

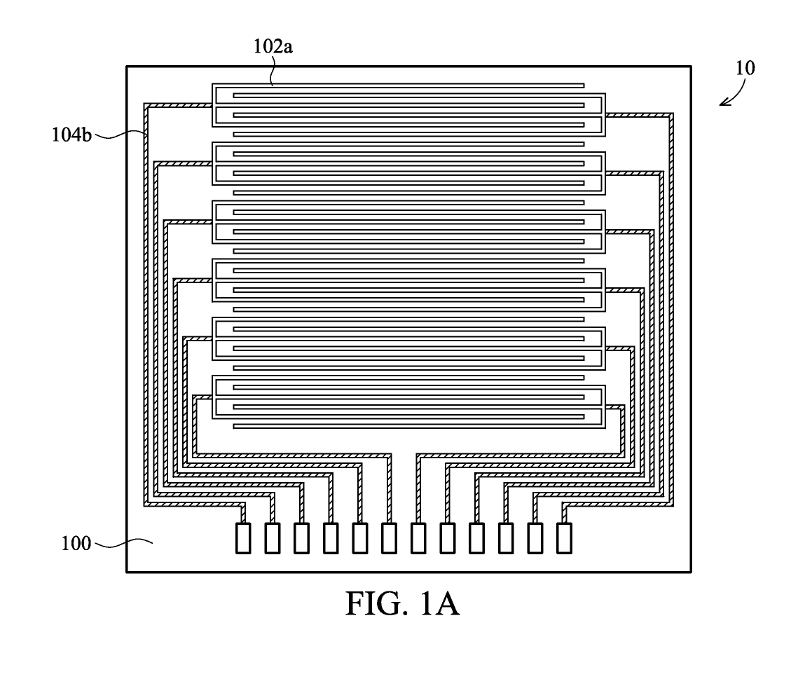

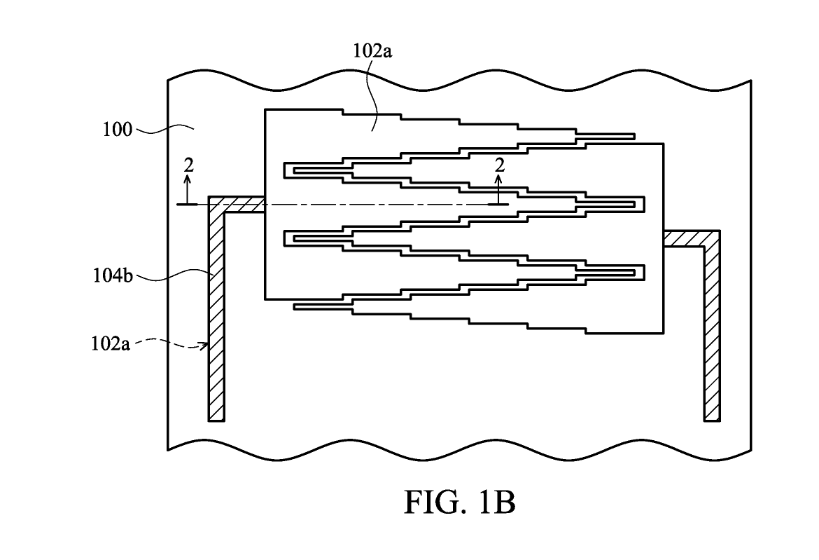

FIG. 1A is a top view showing a touch panel according to an embodiment of the present invention. As shown in FIG. 1A, in one embodiment, a touch panel 10 may include a substrate 100. A transparent conducting pattern layer 102a is formed on the substrate 100, which may include a plurality of sensing electrodes. Wire layers 104b are also formed on the substrate, which are electrically connected to the sensing electrodes, correspondingly and respectively, for transmitting touch-control signals.

FIG. 1B is a top view partially showing a touch panel according to an embodiment of the present invention, which is, for example, an enlarged view partially showing the embodiment shown in FIG. 1A. As shown in FIG. 1B, a width of the sensing electrode of the transparent conducting pattern layer 102a may gradually become wide or narrow along the X axis. Thus, the X-coordinate of a touched position may be accordingly determined. In one embodiment, a lower surface of the wire layer 104b is separated from the substrate 100 by a portion of the transparent conducting pattern layer 102a, which may reduce impedance of the wire layer.

As shown in FIGS. 1A and 1B, in one embodiment, the transparent conducting pattern layer 102a may include at least one first comb electrode and at least one second comb electrode. The first comb electrode may include a plurality of first electrodes, and the first electrodes extend along a direction and are electrically connected to each other, which may be, for example, the first comb electrode extending from the left side towards the right side in FIG. 1A. The second comb electrode may include a plurality of second electrodes, and the second electrodes extend along a direction and are electrically connected to each other, which may be, for example, the second comb electrode extending from the right side towards the left side in FIG. 1A. The second electrodes and the first electrodes may be arranged in a staggered manner, and the first comb electrode and the second comb electrode are electrically insulated from each other.

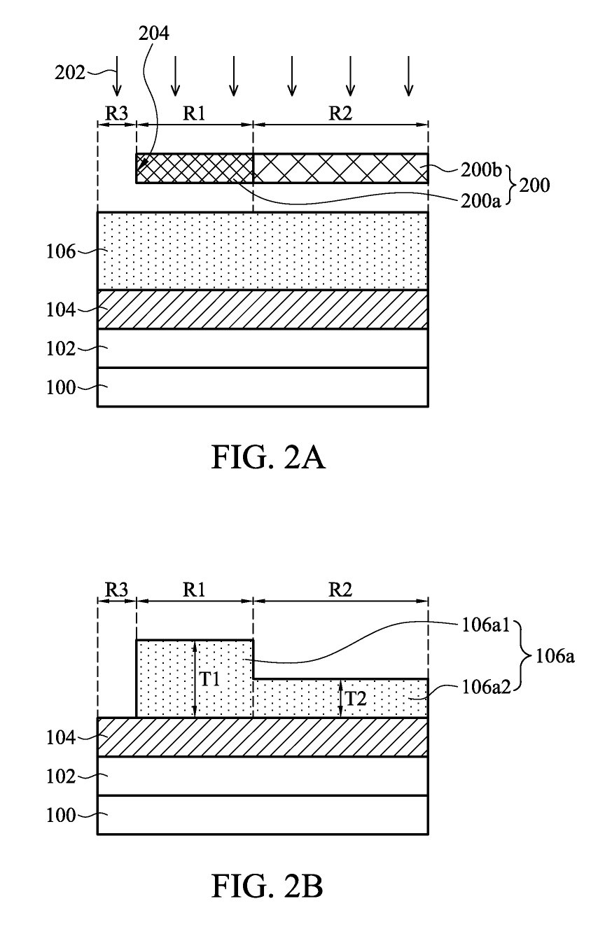

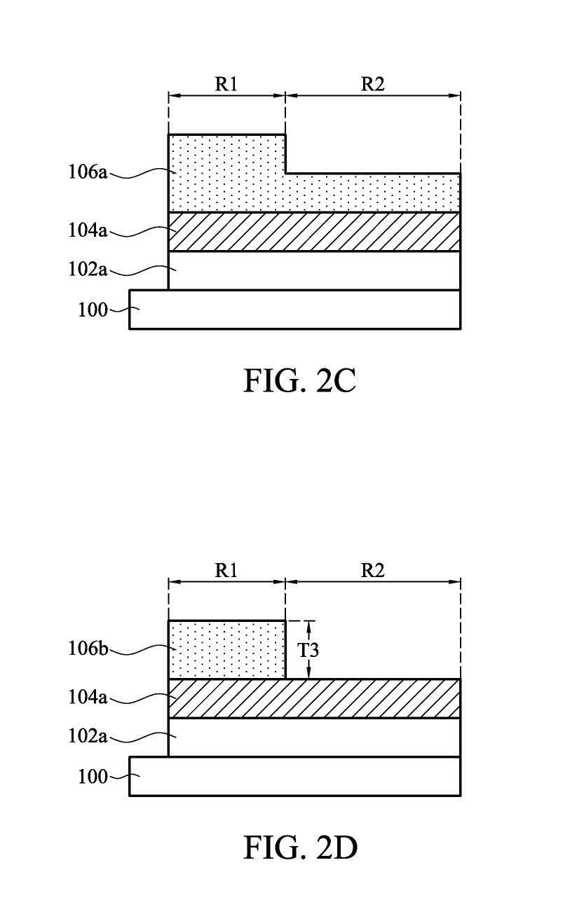

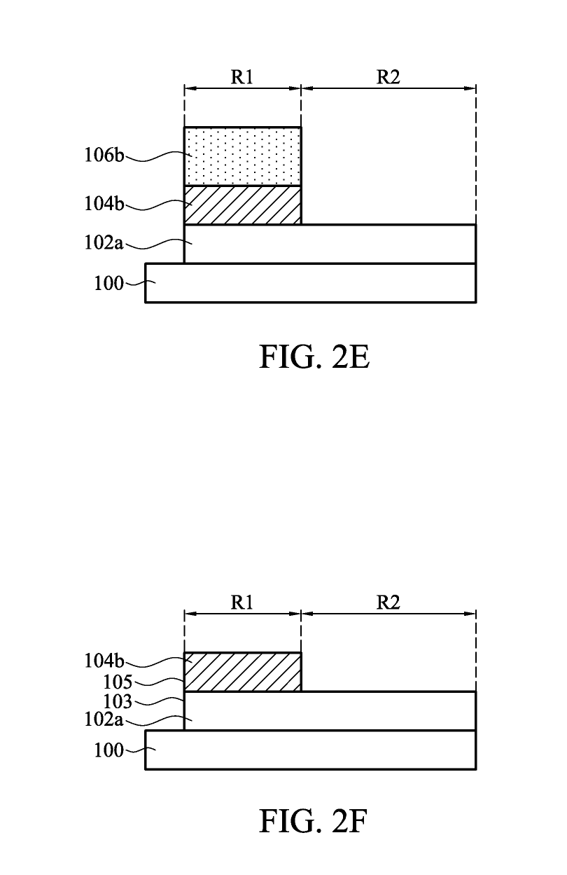

Thereafter, fabrication processes of a touch panel according to an embodiment of the invention are illustrated with references made to cross-sectional views taken along the line 2-2 in FIG. 1B, as shown in FIGS. 2A-2F. As shown in FIG. 2A, in one embodiment, a substrate 100 is provided, and a transparent conducting layer 102, a conducting layer 104, and a photoresist material layer 106 may be sequentially deposited on the substrate 100. The transparent conducting layer 102 may include, for example, an indium tin oxide layer, indium zinc oxide layer, or combinations thereof. The conducting layer 104 is, for example, a metal layer. The conducting layer 104 may have a conductivity larger than that of the transparent conducting layer 102.

Then, a photomask 200 may be disposed on the photoresist material layer 106. The photomask 200 may have a transparent opening 204 which exposes a portion of the photoresist material layer 106 in a region R3. The photomask 200 may have a first portion 200a and a second portion 200b in a region R1 and a region R2, respectively. The first portion 200a has a transmittance less than that of the second portion 200b. Then, light 202 may be provided on the photomask 200 to perform an exposure process and a subsequent development process to the photoresist material layer 106 to pattern the photoresist material layer 106 into a photoresist layer 106a.

As shown in FIG. 2B, the patterned photoresist layer 106a may have a first portion 106a1 and a second portion 106a2 which have a larger thickness T1 and a smaller thickness T2, respectively. The conducting layer 104 in the region R3 is not covered by the photoresist layer 106a. That is, the photoresist layer 106a has at least an opening exposing a portion of the conducting layer 104.

Next, as shown in FIG. 2C, the photoresist layer 106a is used as a mask, and the exposed conducting layer 104 and a portion of the transparent conducting layer 102 thereunder are etched and removed to form a patterned conducting layer 104a and a transparent conducting pattern layer 102a. In one embodiment, the exposed conducting layer 104 and the portion of the transparent conducting layer 102 thereunder may be stepwise etched and removed. For example, an etchant which is suitable for etching a metal material may be first used to etch and remove the exposed conducting layer 104. An etchant which is suitable for etching an oxide material may then be used to etch and remove the portion of the transparent conducting layer 102 thereunder.

As shown in FIG. 2D, the second portion 106a2 of the photoresist layer 106a may then be removed to form a photoresist layer 106b. In one embodiment, an ashing process may be performed to the photoresist layer 106a by using, for example (but is not limited to), a plasma treatment process to remove the second portion 106a2 of the photoresist layer 106a. In one embodiment, after the second portion 106a2 of the photoresist layer 106a is removed, the thickness of the first portion 106a1 of the photoresist layer 106a (i.e., the subsequently formed photoresist layer 106b) is reduced from the thickness T1 to a thickness T3. After the second portion 106a2 of the photoresist layer 106a is removed, a portion of the conducting layer 104 is exposed. The exposed conducting layer 104 is located in, for example, a touch-control sensing region of the touch panel.

Next, the photoresist layer 106b is used as a mask, and the exposed conducting layer 104a is etched and removed to further pattern the patterned conducting layer 104a into a wire layer 104b. In the region R2, the transparent conducting pattern layer 102a originally covered by the patterned conducting layer 104a is exposed to serve as a touch-control sensing electrode, as shown in FIGS. 2E and 1B.

As shown in FIG. 2F, the photoresist layer is then removed to accomplish fabrication of the touch panel. In one embodiment, a side surface 105 of the wire layer 104b is substantially coplanar with a side surface 103 of the transparent conducting pattern layer 102a. In one embodiment, the transparent conducting pattern layer 102a does not cover any side surface of the wire layer 104b. In other words, the transparent conducting pattern layer 102a only covers the top surface of the wire layer 104b. In one embodiment, a lower surface of the wire layer 104b directly contacts with the transparent conducting pattern layer 102a, and is separated from the substrate 100 by the transparent conducting pattern layer 102a.

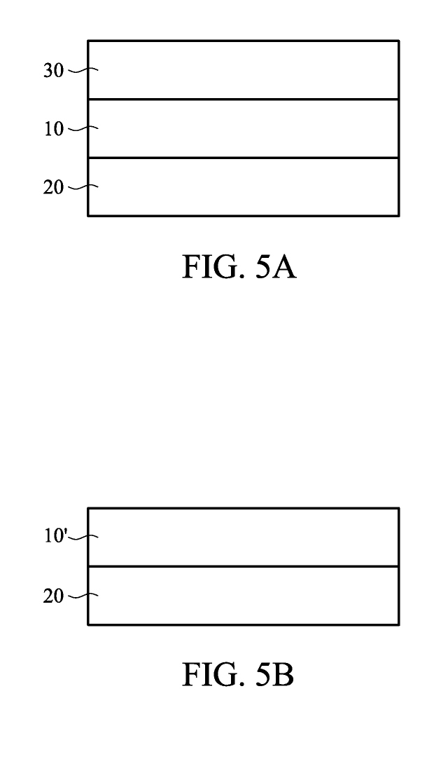

In one embodiment, a transparent cover 30 may be disposed on the touch panel shown in FIG. 2F, as shown in the display system in FIG. 5A. The display system may include a display panel 20 disposed under the touch panel 10.

As shown in the display system in FIG. 5B, in one embodiment, a substrate 100 of the touch panel 10′ may be a transparent cover. Thus, in the display system shown in FIG. 5B, no transparent cover needs to be additionally disposed, which may reduce a thickness of the display system.

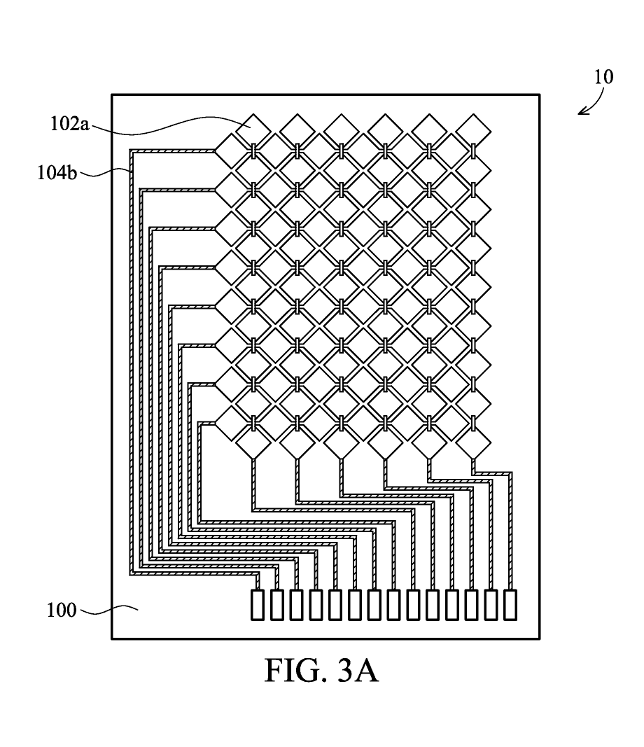

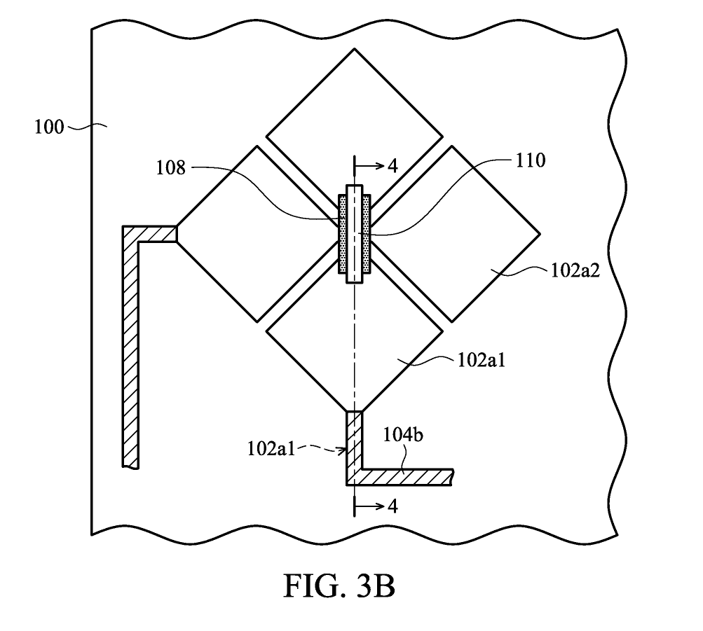

FIG. 3A is a top view showing a touch panel according to an embodiment of the present invention, wherein same or similar reference numbers are used to designate same or similar elements. As shown in FIG. 3A, in one embodiment, a touch panel 10 may include a substrate 100. A transparent conducting pattern layer 102a is formed on the substrate 100, which may include a plurality of sensing electrodes. Wire layers 104b are also formed on the substrate 100, which are electrically connected to the sensing electrodes to transmit touch-control signals.

FIG. 3B is a top view partially showing a touch panel according to an embodiment of the present invention, which is, for example, an enlarged view partially showing the embodiment in FIG. 3A. As shown in FIGS. 3A and 3B, the transparent conducting pattern layer 102a may include at least one first electrode string extending along a first direction (such as the transverse axis direction in FIGS. 3A and 3B or the X axis direction), wherein the first electrode string includes a plurality of first electrode patterns 102a2, and the first electrode patterns 102a2 are electrically connected to each other along the first direction. The transparent conducting pattern layer 102a may also include at least one second electrode string extending along a second direction (such as the ordinate axis direction in FIGS. 3A and 3B or the Y axis direction). The second electrode string includes a plurality of second electrode patterns 102a1 arranged along the second direction, wherein each of the second electrode patterns 102a1 is disposed apart from each other, and the first electrode string and the second electrode string are electrically insulated from each other. The plurality of second electrode patterns of the second electrode string may be electrically connected to each other through at least a bridge structure 110. In addition, in order to prevent short circuiting, a dielectric layer 108 may be formed between the bridge structure 110 and the first electrode pattern 102a2.

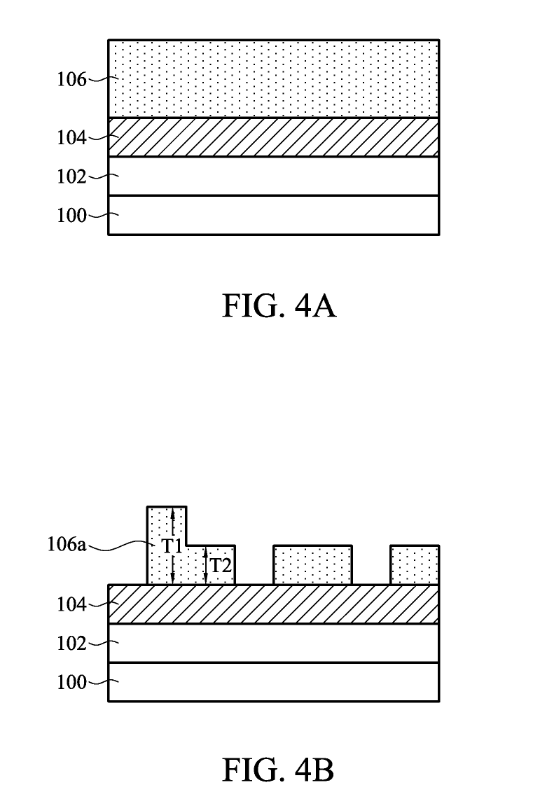

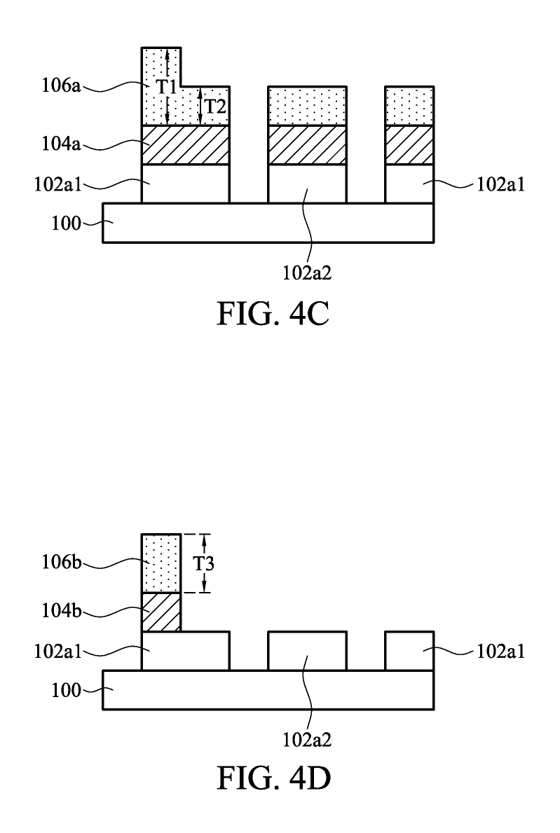

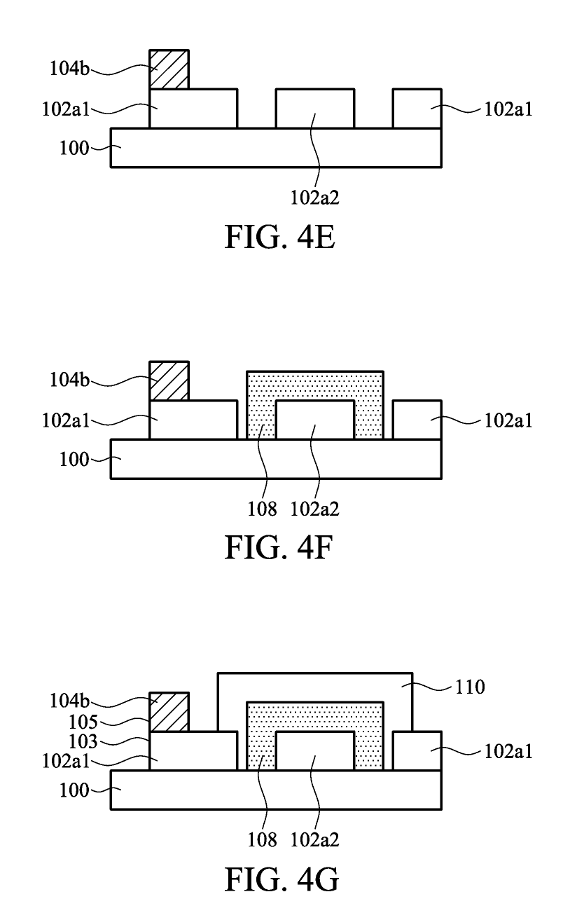

In one embodiment, a lower surface of the wire layer 104b is separated from the substrate 100 by a portion of the transparent conducting pattern layer 102a, which may reduce impedance of the wire layer. Next, fabrication processes of a touch panel according to an embodiment of the invention are illustrated with references made to cross-sectional views taken along the line 4-4 in FIG. 3B, as shown in FIGS. 4A-4G.

As shown in FIGS. 4A-4B, by using methods similar to those illustrated in FIGS. 2A-2B, a patterned photoresist layer 106a may be formed on a substrate 100, a transparent conducting layer 102, and a conducting layer 104. The photoresist layer 106a may include a first portion having a larger thickness T1 and a second portion having a smaller thickness T2. The photoresist layer 106a may also have at least an opening exposing a portion of the conducting layer 104.

Next, as shown in FIG. 4C, the photoresist layer 106a is used as a mask, and the exposed conducting layer 104 and a portion of the transparent conducting layer 102 thereunder are etched and removed to form a patterned conducting layer 104a and a transparent conducting pattern layer 102a. As mentioned above, the transparent conducting pattern layer 102a may include a first electrode string and a second electrode string which may include the first electrode patterns 102a2 and the second electrode patterns 102a1, respectively. In one embodiment, the exposed conducting layer 104 and the portion of the transparent conducting layer 102 may be stepwise etched and removed.

As shown in FIG. 4D, by using a method similar to that illustrated in FIG. 2D, the second portion of the photoresist layer 106a may then be removed to form a photoresist layer 106b, wherein the thickness of the photoresist layer 106b is reduced to a thickness T3. After the second portion of the photoresist layer 106a is removed, a portion of the conducting layer 104a is exposed. The exposed conducting layer 104a is located in, for example, a touch-control region of the touch panel.

Next, the photoresist layer 106b is used as a mask, and the exposed conducting layer 104a is etched and removed to pattern the conducting layer 104a into a wire layer 104b. The portion of the transparent conducting pattern layer 102a originally covered by the conducting layer 104a is exposed to serve as a touch-control sensing electrode, as shown in FIGS. 4F and 3B. As shown in FIG. 4E, the photoresist layer may then be removed.

As shown in FIG. 4F, at least a dielectric layer 108 is then formed on the substrate 100 and the transparent conducting pattern layer 102a. Then, a bridge structure 110 is formed on the dielectric layer 108 and a portion of the transparent conducting pattern layer 102a (i.e., a portion of the second electrode patterns 102a1 of the transparent conducting pattern layer 102a), wherein the bridge structure 110 electrically connects to the second electrode patterns 102a1, and the dielectric layer electrically insulates the bridge structure 110 from the first electrode string.

In one embodiment, a side surface 105 of the wire layer 104b is substantially coplanar with a side surface 103 of the transparent conducting pattern layer 102a. In one embodiment, the transparent conducting pattern layer 102a does not cover any side surface of the wire layer 104b. In other words, the transparent conducting pattern layer 102a only covers the top surface of the wire layer 104b. In one embodiment, a lower surface of the wire layer 104b directly contacts with the transparent conducting pattern layer 102a, and is separated from the substrate 100 by the transparent conducting pattern layer 102a.

In the embodiments of the present invention, due to the formation of the photoresist layer having uneven thicknesses, touch-control sensing electrodes and wire layers of the touch panel are formed in a patterning process requiring only a single photomask. Fabrication time and fabrication cost may be effectively reduced, and reliability of the touch panel may be improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a touch panel, comprising:
providing a substrate;
forming a transparent conducting layer on the substrate;
forming a conducting layer on the transparent conducting layer;
forming a photoresist layer on the conducting layer, wherein the photoresist layer has a first portion, a second portion, and at least one opening, and the first portion has a thickness larger than that of the second portion, and the opening exposes a portion of the conducting layer;
using the photoresist layer as a mask to etch and remove the exposed conducting layer and the transparent conducting layer thereunder such that the transparent conducting layer is formed to be a transparent conducting pattern layer;
removing the second portion of the photoresist layer to expose a portion of the conducting layer thereunder;
using the photoresist layer as a mask to etch and remove the exposed conducting layer such that the conducting layer is formed to be a wire layer; and
removing the photoresist layer.

2. The method for forming a touch panel as claimed in claim 1, wherein the step of forming the photoresist layer comprises:
forming a photoresist material layer on the conducting layer;
disposing a photomask on the photoresist material layer, wherein the photomask has a first transparent portion, a second transparent portion, and at least a transparent opening, and the first transparent portion has a transmittance larger than that of the second transparent portion, and the transparent opening exposes a portion of the photoresist material layer; and
performing an exposure process and a development process such that the photoresist material layer is patterned to be the photoresist layer.

3. The method for forming a touch panel as claimed in claim 1, wherein the step of using the photoresist layer as the mask to etch and remove the exposed conducting layer and the transparent conducting layer thereunder comprises etching and removing the exposed conducting layer by using a first etchant and etching and removing the transparent conducting layer thereunder by using a second etchant.

4. The method for forming a touch panel as claimed in claim 1, wherein the step of removing the second portion of the photoresist layer comprises performing an ashing process on the photoresist layer to remove the second portion of the photoresist layer.

5. The method for forming a touch panel as claimed in claim 4, wherein the ashing process comprises a plasma treatment process.

6. The method for forming a touch panel as claimed in claim 1, wherein after the step of removing the second portion of the photoresist layer is performed, the thickness of the first portion of the photoresist layer is reduced.

7. The method for forming a touch panel as claimed in claim 1, wherein the transparent conducting pattern layer comprises:
a first comb electrode having a plurality of first electrodes, wherein the first electrodes extend along a direction and are electrically connected to each other; and
a second comb electrode having a plurality of second electrodes, wherein the second electrodes and the first electrodes are arranged in a staggered manner, and the second electrodes extend along an opposite direction of the direction and are electrically connected to each other, and the first comb electrode and the second comb electrode are electrically insulated from each other.

8. The method for forming a touch panel as claimed in claim 1, wherein the transparent conducting pattern layer comprises:
at least one first electrode string extending along a first direction, wherein the first electrode string comprises a plurality of first electrode patterns, and the first electrode patterns are electrically connected to each other along the first direction; and
a plurality of second electrode patterns arranged along a second direction, wherein each of the second electrode patterns is disposed apart from each other, and the first electrode string and the second electrode patterns are electrically insulated from each other.

9. The method for forming a touch panel as claimed in claim 8, further comprising:
forming a dielectric layer on the substrate and a portion of the first electrode string; and
forming at least a bridge structure on the dielectric layer and a portion of the second electrode patterns, wherein the bridge structure electrically connects to the second electrode patterns, and the dielectric layer electrically isolates the bridge structure from the first electrode string.

10. The method for forming a touch panel as claimed in claim 9, wherein the bridge structure comprises a transparent conducting material.

11. The method for forming a touch panel as claimed in claim 1, further comprising disposing a transparent cover on the substrate, wherein the conducting layer and the transparent conducting layer are located between the substrate and the transparent cover.

12. A touch panel, comprising:
a substrate;
a transparent conducting pattern layer disposed on the substrate; and
a wire layer formed on the transparent conducting pattern layer, wherein a lower surface of the wire layer is separated from the substrate by a portion of the transparent conducting pattern layer.

13. The touch panel as claimed in claim 12, wherein a side surface of the wire layer is substantially coplanar with a side surface of the transparent conducting pattern layer.

14. The touch panel as claimed in claim 12, wherein the transparent conducting pattern layer covers only a top surface of the wire layer.

15. The touch panel as claimed in claim 12, wherein the lower surface of the wire layer directly contacts with the transparent conducting pattern layer.

16. The touch panel as claimed in claim 12, wherein the wire layer has a conductivity larger than that of the transparent conducting pattern layer.

17. The touch panel as claimed in claim 12, wherein the transparent conducting pattern layer comprises:
at least one first electrode string disposed on the substrate and extending along a first direction, wherein the first electrode string comprises a plurality of first electrode patterns, and the first electrode patterns are electrically connected to each other along the first direction;
a plurality of second electrode patterns disposed on the substrate and arranged along a second direction, wherein each of the second electrode patterns is disposed apart from each other, and the first electrode string and the second electrode patterns are electrically insulated from each other;
a dielectric layer disposed on the substrate and a portion of the first electrode string; and
at least one bridge structure disposed on the dielectric layer and a portion of the second electrode patterns, wherein the bridge structure electrically connects to the second electrode patterns, and the dielectric layer electrically isolates the bridge structure from the first electrode string.

18. The touch panel as claimed in claim 17, wherein the bridge structure comprises a transparent conducting material.

19. The touch panel as claimed in claim 12, wherein the transparent conducting pattern layer comprises:
a first comb electrode having a plurality of first electrodes, wherein the first electrodes extend along a direction and are electrically connected to each other; and
a second comb electrode having a plurality of second electrodes, wherein the second electrodes and the first electrodes are arranged in a staggered manner, and the second electrodes extend along an opposite direction of the direction and are electrically connected to each other, and the first comb electrode and the second comb electrode are electrically insulated from each other.

20. A display system, comprising:
a display panel; and
a touch panel disposed on the display panel, wherein the touch panel comprises:
a substrate;
a transparent conducting pattern layer disposed on the substrate; and
a wire layer formed on the transparent conducting pattern layer, wherein a lower surface of the wire layer is separated from the substrate by a portion of the transparent conducting pattern layer.
